(19) United States
(12) Patent Application Publication
(10) Pub. No.: US 2017/0326868 A1
(43) Pub. Date: Nov. 16, 2017

(54) MULTI-MATERIAL WIRES FOR ADDITIVE MANUFACTURING OF TITANIUM ALLOYS

(71) Applicant: ARCONIC INC., Pittsburgh, PA (US)

(72) Inventors: David W. Heard, Pittsburgh, PA (US); Gen Satoh, Murrysville, PA (US); Vivek M. Sample, Murrysville, PA (US); Andreas Kulovits, Pittsburgh, PA (US); Raymond J. Kilmer, Pittsburgh, PA (US)

(21) Appl. No.: 15/595,493

(22) Filed: May 15, 2017

Related U.S. Application Data
(60) Provisional application No. 62/336,898, filed on May 16, 2016.

(51) Int. Cl. B33Y 70/00; C22C 21/00; C22C 14/00; H01J 37/30; B33Y 99/00

(52) U.S. Cl. CPC B33Y 70/00; H01J 37/30; B33Y 99/00; C22C 14/00; C22C 21/003

(57) ABSTRACT

Wires for use in electron beam or plasma arc additive manufacturing of titanium alloys are disclosed. The wires have a first portion comprising a first material, and a second portion comprising a second material. The combination of the first and second materials results in a titanium alloy product of the appropriate composition.

### CROSS-REFERENCE TO RELATED APPLICATION

This patent application claims benefit of priority of U.S. Provisional Patent Application No. 62/336,898, filed May 16, 2016, entitled “MULTI-MATERIAL WIRES FOR ADDITIVE MANUFACTURING OF TITANIUM ALLOYS”, which is incorporated herein by reference in its entirety.

### BACKGROUND

Ti-6Al-4V is one of the most widely used titanium alloys. Ti-6A-4V is an alpha-beta type titanium alloy containing 6 wt. % Al and 4 wt. % V. Ti-6Al-4V is known for its good combination of strength, toughness and corrosion resistance.

### SUMMARY OF THE INVENTION

Broadly, the present disclosure relates to new multi-material wires for additive manufacturing of titanium alloys, such as additive manufacturing techniques employing an electron beam and/or plasma arc radiation source.

In one approach, a wire for use in electron beam or plasma arc additive manufacturing is provided. In this approach, the wire may include an outer tube portion and a volume of particles contained within the outer tube portion. The outer tube portion comprises a first material or a second material, and the volume of particles generally comprise the other of the first material and the second material relative to the outer tube portion. In one embodiment, the second material at least comprises titanium. In one embodiment, the second material comprises an aluminum-containing titanium alloy. In one embodiment, the second material is a titanium alloy selected from the group consisting of Ti-6Al-4V, Ti-6Al-6V-2Sn, Ti-7Al-4Mo, Ti-6Al-2Sn-4Zr-6Mo, Ti-5Al-2Sn-2Zr-4Mo-4Cr, Ti-6Al-2Sn-2Zr-2Mo-2Cr, Ti-3Al-2.5V, Ti-10V-2Fe-3Al, Ti-13V-11Cr-3Al, Ti-8Mo-8V-2Fe-3Al, Ti-3Al-8V-6Cr-4Mo-4Zr, Ti-5Al-2.5Sn, Ti-8Al-1Mo-1V, Ti-6Al-2Sn-4Zr-2Mo, Ti-6Al-2Nb-1Ta-0.8Mo, Ti-2.25Al-11Sn-5Zr-1Mo, and Ti-5Al-5Sn-2Zr-2Mo. In one embodiment, the first material comprises an element for alloying with titanium, such as one or more of aluminum, tin, molybdenum, niobium, vanadium, zirconium, chromium, and iron, among others. In one embodiment, the first material is selected from the group consisting of aluminum, tin, molybdenum, niobium, vanadium, zirconium, chromium, iron and combinations thereof. In one embodiment, the first material comprises aluminum or an aluminum alloy. In one embodiment, the first material comprises elemental aluminum or a 1xxx alloy. In one embodiment, the first material is essentially free of titanium. The combined compositions of the first material and second material are generally sufficient to produce a titanium alloy product when the wire is used in additive manufacturing. For instance, the wire may include a sufficient amount of the first material and the second material to achieve a target composition of a final titanium alloy product. In one embodiment, the first material is a 1xxx aluminum alloy and the second material is Ti-6Al-4V.

In another approach, a wire for use in electron beam or plasma arc additive manufacturing is provided, the wire including a first elongate outer tube and a second elongate inner tube disposed within the first elongate outer tube. The first elongate outer tube generally comprises a first material or a second material, and the second elongate inner tube generally comprise the other of the first material and the second material relative to the first elongate outer tube. In one embodiment, the second material at least comprises titanium. In one embodiment, the second material comprises an aluminum-containing titanium alloy. In one embodiment, the second material is a titanium alloy selected from the group consisting of Ti-6Al-4V, Ti-6Al-6V-2Sn, Ti-7Al-4Mo, Ti-6Al-2Sn-4Zr-6Mo, Ti-5Al-2Sn-2Zr-4Mo-4Cr, Ti-6Al-2Sn-2Zr-2Mo-2Cr, Ti-3Al-2.5V, Ti-10V-2Fe-3Al, Ti-13V-11Cr-3Al, Ti-8Mo-8V-2Fe-3Al, Ti-3Al-8V-6Cr-4Mo-4Zr, Ti-5Al-2.5Sn, Ti-8Al-1Mo-1V, Ti-6Al-2Sn-4Zr-2Mo, Ti-6Al-2Nb-1Ta-0.8Mo, Ti-2.25Al-11Sn-5Zr-1Mo, and Ti-5Al-5Sn-2Zr-2Mo. In one embodiment, the first material comprises an element for alloying with titanium, such as one or more of aluminum, tin, molybdenum, niobium, vanadium, zirconium, chromium, and iron, among others. In one embodiment, the first material is selected from the group consisting of aluminum, tin, molybdenum, niobium, vanadium, zirconium, chromium, iron and combinations thereof. In one embodiment, the first material comprises aluminum or an aluminum alloy. In one embodiment, the first material comprises elemental aluminum or a 1xxx alloy. In one embodiment, the first material is essentially free of titanium. The combined compositions of the first material and second material are generally sufficient to produce a titanium alloy product when the wire is used in additive manufacturing. For instance, the wire may include a sufficient amount of the first material and the second material to achieve a target composition of a final titanium alloy product. In one embodiment, the first material is a 1xxx aluminum alloy and the second material is Ti-6Al-4V.

In another approach, a wire for use in electron beam or plasma arc additive manufacturing is provided, the wire including a first fiber and a second fiber intertwined with the first fiber. The first fiber generally comprises a first material, and the second fiber generally comprises a second material, different than the first material. In one embodiment, the second material at least comprises titanium. In one embodiment, the second material comprises an aluminum-containing titanium alloy. In one embodiment, the second material is a titanium alloy selected from the group consisting of Ti-6Al-4V, Ti-6Al-6V-2Sn, Ti-7Al-4Mo, Ti-6Al-2Sn-4Zr-6Mo, Ti-5Al-2Sn-2Zr-4Mo-4Cr, Ti-6Al-2Sn-2Zr-2Mo-2Cr, Ti-3Al-2.5V, Ti-10V-2Fe-3Al, Ti-13V-11Cr-3Al, Ti-8Mo-8V-2Fe-3Al, Ti-3Al-8V-6Cr-4Mo-4Zr, Ti-5Al-2.5Sn, Ti-8Al-1Mo-1V, Ti-6Al-2Sn-4Zr-2Mo, Ti-6Al-2Nb-1Ta-0.8Mo, Ti-2.25Al-11Sn-5Zr-1Mo, and Ti-5Al-5Sn-2Zr-2Mo. In one embodiment, the first material comprises an element for alloying with titanium, such as one or more of aluminum, tin, molybdenum, niobium, vanadium, zirconium, chromium, and iron, among others. In one embodiment, the first material is selected from the group consisting of aluminum, tin, molybdenum, niobium, vanadium, zirconium, chromium, iron and combinations thereof. In one embodiment, the first material comprises aluminum or an aluminum alloy. In one embodiment, the first material comprises elemental aluminum or a 1xxx alloy. In one embodiment, the first material is essentially free of titanium. The combined compositions of the first material and the second material are generally sufficient to produce a titanium alloy product when the wire is used in additive manufacturing. For instance, the wire may include a sufficient amount of the first material and the second material to achieve a target composition of a final titanium alloy product. In one embodiment, the first material is a 1xxx aluminum alloy and the second material is Ti-6Al-4V.

Methods of using the above-described wires are also disclosed. In one embodiment, a method includes using a radiation source to heat any of the above-described wires above the liquidus point of the titanium alloy body to be formed, thereby creating a molten pool, and cooling the molten pool at a cooling rate of at least 1000° C. per second. These steps may be repeated as necessary (e.g., during additive manufacturing) until the final titanium alloy product is completed.

### BRIEF DESCRIPTION OF THE DRAWINGS

FIG. 1a is a schematic view of one embodiment of using electron beam additive manufacturing to produce a titanium alloy body.

FIG. 1b illustrates an embodiment of a wire useful with the electron beam embodiment of FIG. 1a, the wire having an elongate outer tube portion and a volume of particles contained within the elongate outer tube portion.

FIGS. 1c-1f illustrates embodiments of wires useful with the electron beam embodiment of FIG. 1a, the wires having an elongate outer tube portion and at least one second elongate inner tube portion. FIGS. 1c and 1e are schematic side views of the wires, and FIGS. 1d and 1f are top-down schematic views of the wires of FIGS. 1c and 1e, respectively.

FIG. 1g illustrates one embodiment of a wire useful with the electron beam embodiment of FIG. 1a, the wire having at least first and second intertwined fibers, wherein the first and second fibers are of different compositions.

### DETAILED DESCRIPTION

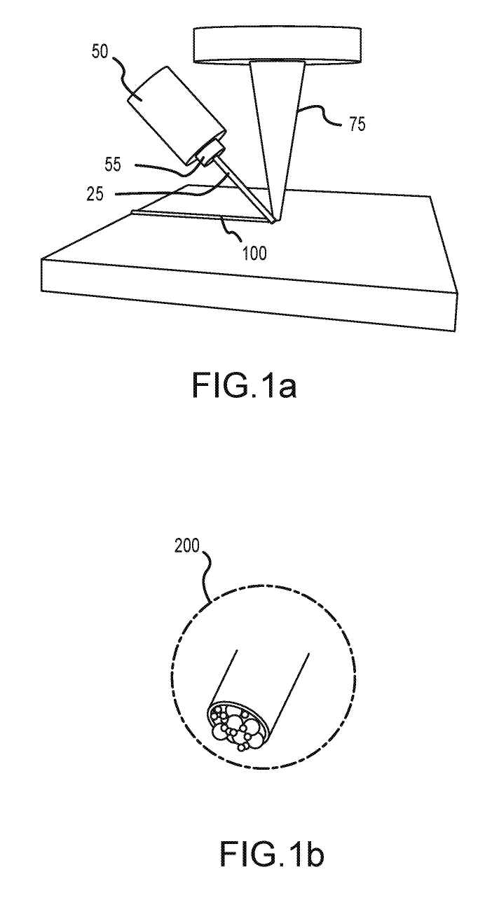

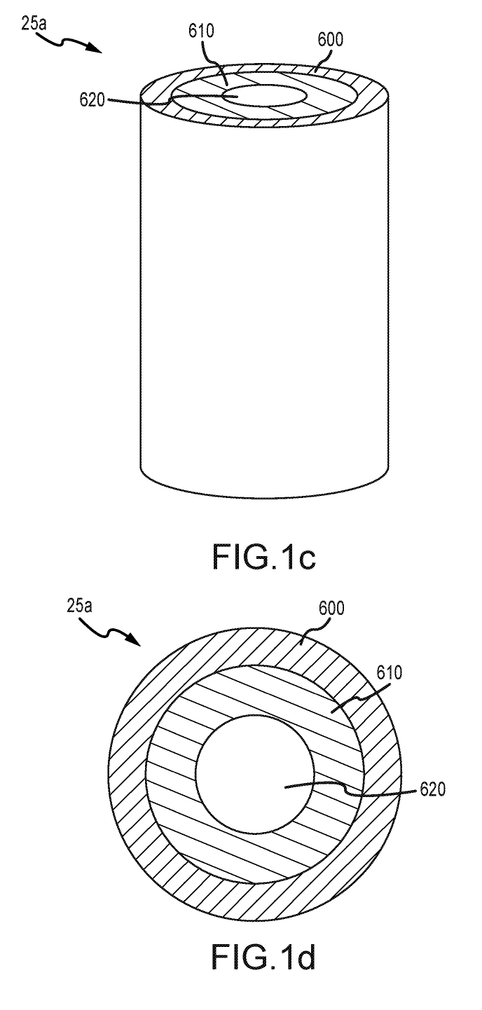

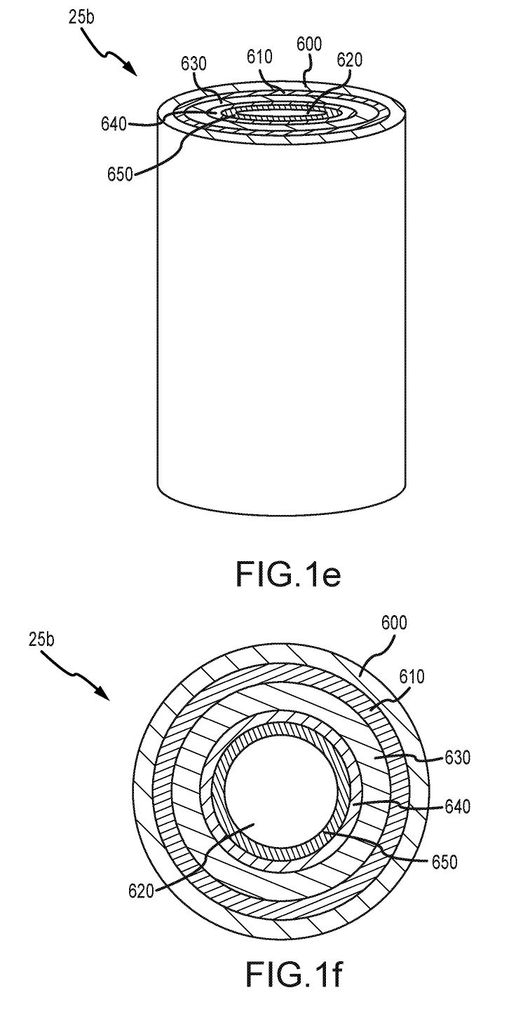

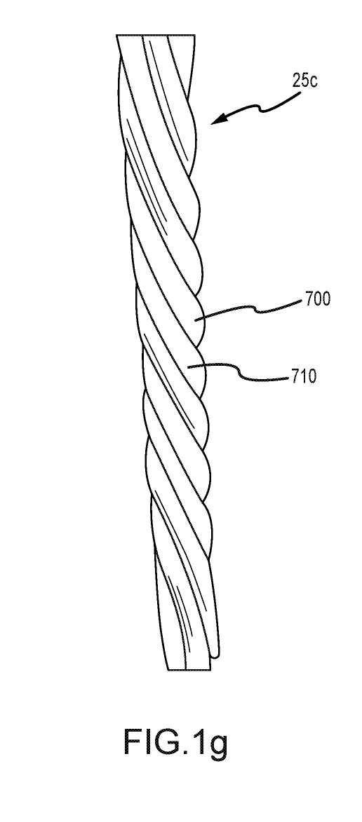

Referring now to FIGS. 1a-1b , one embodiment of a multi-material wire is illustrated. In the illustrated embodiment, the multi-material wire (25) is a powder core wire (200) having an elongate outer tube portion and a volume of particles contained within the elongate outer tube portion. The elongate outer tube portion generally comprises a first material or a second material, and the volume of particles generally comprises the other of the first material or the second material, the second material being different than the first material. For instance, if the elongate outer tube portion comprises the first material, the volume of particles comprises the second material. On the other hand, if the elongate outer tube portion comprises the second material, the volume of particles comprises the first material. In any event, the compositions of the first material and second material are generally sufficient to produce a titanium alloy product when the wire is used in additive manufacturing. For instance, the first material may comprise aluminum and the second material may comprise titanium, such as an aluminum-containing titanium alloy. During additive manufacturing, the wire (25) is fed from a wire feeder portion (55) of a wire feeder gun (50) towards a building substrate. The electron beam (75) or other suitable radiation source heats the wire (25) above the liquidus point of the titanium alloy body to be formed, thereby forming a molten pool, which is followed by rapid solidification (e.g., ≧1000° C. per second) of the molten pool to form the deposited titanium alloy material (100). These steps may be repeated as necessary until the final titanium alloy body is produced. During such an additive manufacturing process, high temperatures may result in volatizing some of the aluminum due to the high partial pressure of aluminum in the molten pool. However, the additional aluminum supplied by the elongate outer tube portion at least partially supplements/replaces the volatized aluminum, thereby facilitating achievement of a target composition for the deposited titanium alloy material (100).

As noted above, the wire comprises a sufficient amount of the second material to produce a titanium alloy product when the wire is used in additive manufacturing, and this second material generally comprises titanium. In one approach, the second material is a titanium alloy. In one embodiment, the second material is an aluminum-containing titanium alloy. In one embodiment, the second material is selected from the group consisting of Ti-6Al-4V, Ti-6Al-6V-2Sn, Ti-7Al-4Mo, Ti-6Al-2Sn-4Zr-6Mo, Ti-5Al-2Sn-2Zr-4Mo-4Cr, Ti-6Al-2Sn-2Zr-2Mo-2Cr, Ti-3Al-2.5V, Ti-10V-2Fe-3Al, Ti-13V-11Cr-3Al, Ti-8Mo-8V-2Fe-3Al, Ti-3Al-8V-6Cr-4Mo-4Zr, Ti-5Al-2.5Sn, Ti-8Al-1Mo-1V, Ti-6Al-2.5n-4Zr-2Mo, Ti-6Al-2Nb-1Ta-0.8Mo, Ti-2.25Al-11Sn-5Zr-1Mo, and Ti-5Al-5Sn-2Zr-2Mo. In one embodiment, the second material is Ti-6Al-4V.

As noted above, the wire comprises a sufficient amount of the first material to produce a titanium alloy product when the wire is used in additive manufacturing, and this first material generally comprises aluminum. In one embodiment, the first material is essentially free of titanium. In one embodiment, the first material is a 1xxx aluminum alloy as defined by the Aluminum Association, i.e., a material comprising at least 99.0 wt. % Al. In another embodiment, the first material comprises at least one secondary element to facilitate achievement of the target titanium alloy composition upon conclusion of the additive manufacturing. In one embodiment, the at least one secondary element is selected from the group of vanadium (V), tin (Sn), molybdenum (Mo), zirconium (Zr), niobium (Nb), chromium (Cr), iron (Fe) and combinations thereof, wherein the first material comprises a sufficient amount of the aluminum and the at least one secondary element to facilitate achievement of the target titanium alloy composition upon conclusion of the additive manufacturing.

As used herein, “additive manufacturing” means “a process of joining materials to make objects from 3D model data, usually layer upon layer, as opposed to subtractive manufacturing methodologies”, as defined in ASTM F2792-12a entitled “Standard Terminology for Additively Manufacturing Technologies”, as it applies to the use of wires. In one embodiment, an additive manufacturing processes uses Electron Beam Melting (EBM). In one embodiment, an additive manufacturing process uses an EOSINT M 280 Direct Metal Laser Sintering (DMLS) additive manufacturing system, or comparable system, available from EOS GmbH (Robert-Stirling-Ring 1, 82152 Krailling/Munich, Germany).

The wire (25) used in the additive manufacturing process may include the appropriate volume of the first material and the second material to achieve the target titanium alloy composition upon conclusion of the additive manufacturing. In this regard, the thickness of the elongate outer tube and/or the volume of particles may be tailored.

In another embodiment, and referring now to FIGS. 1c-1d, the wire (25a) is a multiple-tube wire having first elongate outer tube portion (600) and at least a second elongate inner tube portion (610). The first portion (600) comprises the first material or the second material, and the second portion (610) comprises the other of the first material or the second material. The wire (25a) may include a hollow core (620), as shown, or may include a solid core or may include a volume of particles within the core, as described above relative to FIGS. 1a-1b. In any event, the collective compositions of the first material, the second material and any materials of the core are such that, after deposition, the target composition for the deposited titanium alloy material (100) is achieved. The first material and second materials may be any of the first and second materials described above relative to FIGS. 1a-1b. Further, as shown in FIGS. 1e-1f, a wire (25b) may include any number of multiple elongate tubes (e.g., tubes 600-610 and 630-650) each of the appropriate composition and thickness to provide the appropriate end composition for the titanium alloy product. As described above relative to FIGS. 1c-1d, the core (620) may be a hollow core (620), as shown, or may include a solid core or may include a volume of particles within the core, as described above relative to FIGS. 1a-1b.

In another embodiment, and referring now to FIG. 1g, the wire (25c) is a multiple-fiber wire having a first fiber (700) and at least a second fiber (710) intertwined with the first wire (100). The first fiber (700) comprises the first material, and the second portion (710) comprises the second material. The collective compositions of the first material and the second material are such that, after deposition, the target composition for the deposited titanium alloy material (100) is achieved.

In another embodiment, not illustrated, an electron beam (EB) or plasma arc additive manufacturing apparatus may employ multiple different wires, optionally with corresponding multiple different radiation sources, each of the wires and sources being fed and activated, as appropriate to provide the target composition for the deposited titanium alloy material (100).

While various embodiments of the new technology described herein have been described in detail, it is apparent that modifications and adaptations of those embodiments will occur to those skilled in the art. However, it is to be expressly understood that such modifications and adaptations are within the spirit and scope of the presently disclosed technology.

What is claimed is:

1. A wire for use in electron beam or plasma arc additive manufacturing, the wire comprising:
an outer tube portion comprising a first material, the first material at least comprising aluminum; and
a volume of particles contained within the outer tube portion, the volume of particles being a second material, wherein the second material is different than the first material and at least comprises titanium;
wherein the composition of the first material and second material are sufficient to produce a titanium alloy product when the wire is used in additive manufacturing.

2. The wire of claim 1, wherein the second material comprises an aluminum-containing titanium alloy.

3. The wire of claim 2, wherein the second material is a titanium alloy selected from the group consisting of Ti-6Al-4V, Ti-6Al-6V-2Sn, Ti-7Al-4Mo, Ti-6Al-2Sn-4Zr-6Mo, Ti-5Al-2Sn-2Zr-4Mo-4Cr, Ti-6Al-2Sn-2Zr-2Mo-2Cr, Ti-3Al-2.5V, Ti-10V-2Fe-3Al, Ti-13V-11Cr-3Al, Ti-8Mo-8V-2Fe-3Al, Ti-3Al-8V-6Cr-4Mo-4Zr, Ti-5Al-2.5Sn, Ti-8Al-1Mo-1V, Ti-6Al-2Sn-4Zr-2Mo, Ti-6Al-2Nb-1Ta-0.8Mo, Ti-2.25Al-11Sn-5Zr-1Mo, and Ti-5Al-5Sn-2Zr-2Mo.

4. The wire of claim 1, wherein the first material is a 1xxx aluminum alloy.

5. The wire of claim 1, wherein the first material comprises a sufficient amount of the aluminum and any secondary elements to achieve the target composition of the titanium alloy product.

6. The wire of claim 5, wherein the secondary elements are selected from the group of vanadium (V), tin (Sn), molybdenum (Mo), zirconium (Zr), niobium (Nb), chromium (Cr), iron (Fe) and combinations thereof.

7. The wire of claim 1, wherein the first material is essentially free of titanium.

8. The wire of claim 1, wherein the first material is a lxxx aluminum alloy and wherein the second material is Ti-6Al-4V.

9. A wire for use in electron beam or plasma arc additive manufacturing, comprising:
(a) a first elongate outer tube;
(i) wherein the first elongate outer tube comprises a first material or a second material
(b) a second elongate inner tube disposed within the first elongate outer tube;
(i) wherein the second elongate inner tube comprise the other of the first material and the second material relative to the first elongate outer tube;
wherein the first material at least comprises aluminum;
wherein the second material is different than the first material and at least comprises titanium;
wherein the composition of the first material and second material are sufficient to produce a titanium alloy product when the wire is used in additive manufacturing.

10. The wire of claim 9, wherein the second material comprises an aluminum-containing titanium alloy.

11. The wire of claim 9, wherein the first material is a 1xxx aluminum alloy.

12. The wire of claim 9, wherein the first material is essentially free of titanium.

13. The wire of claim 9, wherein the first material is a 1xxx aluminum alloy and wherein the second material is Ti-6Al-4V.

14. A wire for use in electron beam or plasma arc additive manufacturing, comprising:
(a) a first fiber;
(i) wherein the first fiber comprises a first material, the first material at least comprising aluminum;
(b) a second fiber intertwined with the first fiber;
(i) wherein the second fiber comprises a second material;
(ii) wherein the second material is different than the first material and at least comprises titanium;
wherein the composition of the first material and second material are sufficient to produce a titanium alloy product when the wire is used in additive manufacturing.

15. The wire of claim 14, wherein the second material comprises an aluminum-containing titanium alloy.

16. The wire of claim 14, wherein the first material is a 1xxx aluminum alloy.

17. The wire of claim 14, wherein the first material is essentially free of titanium.

18. The wire of claim 14, wherein the first material is a 1xxx aluminum alloy and wherein the second material is Ti-6Al-4V.
